(19) United States
(12) Patent Application Publication
(10) Pub. No.: US 2014/0087559 A1
(43) Pub. Date: Mar. 27, 2014

(54) SEMICONDUCTOR STRUCTURE AND MANUFACTURING METHOD OF THE SAME

(71) Applicants: Xu-Yang Shen, Singapore (SG); Seng-Wah Liau, Singapore (SG); Jian-Jun Zhang, Singapore (SG); Han-Chuan Fang, Singapore (SG)

(72) Inventors: Xu-Yang Shen, Singapore (SG); Seng-Wah Liau, Singapore (SG); Jian-Jun Zhang, Singapore (SG); Han-Chuan Fang, Singapore (SG)

(73) Assignee: UNITED MICROELECTRONICS CORP., Hsinchu (TW)

(21) Appl. No.: 13/628,125

(22) Filed: Sep. 27, 2012

(51) Int. Cl. H01L 21/302; H01L 21/768

(52) U.S. Cl. 438/675; 438/702; 257/E21.586; 257/E21.214

(57) ABSTRACT

A method for forming a semiconductor structure and a method for patterning a dielectric layer are provided. The method comprises following steps. An upper cap layer is formed on and physically contacted with a dielectric layer. The dielectric layer has a dielectric thickness having a range of 1000 Å˜5000 Å. A patterned mask layer is formed on and physically contacted with the upper cap layer. A part of the upper cap layer is removed to form a patterned upper cap layer by using the patterned mask layer as an etching mask. A part of the dielectric layer is removed to form a dielectric opening in the dielectric layer by using the patterned upper cap layer as an etching mask.

### BACKGROUND

1. Technical Field

The disclosure relates in general to a method for forming a semiconductor structure and more particularly to a method for patterning a dielectric layer.

2. Description of the Related Art

In recent years, semiconductor structures have been changed continuously, and the steps of manufacturing the semiconductor structure have been increased correspondingly, which may cause the process yields to drop undesirably. In particular, when there are defects on a surface of an element, the yields of the subsequent manufacturing processes would drop easily.

As such, it is desirable to decrease the defects in semiconductor manufacturing processes, hence to improve the process yields of product.

### SUMMARY

A method for forming a semiconductor structure is provided. The method comprises following steps. An upper cap layer is formed on and physically contacted with a dielectric layer. The dielectric layer has a dielectric thickness having a range of 1000 Å˜5000 Å. A patterned mask layer is formed on and physically contacted with the upper cap layer. A part of the upper cap layer is removed to form a patterned upper cap layer by using the patterned mask layer as an etching mask. A part of the dielectric layer is removed to form a dielectric opening in the dielectric layer by using the patterned upper cap layer as an etching mask.

A method for patterning a dielectric layer is provided. The method comprises following steps. An upper cap layer is formed on and physically contacted with a dielectric layer. The dielectric layer has a dielectric thickness having a range of 1000 Å˜5000 Å. The upper cap layer has an upper cap thickness having a range of 300 Å˜2000 Å. A patterned mask layer is formed on and physically contacted with the upper cap layer. The patterned mask layer has a mask thickness having a range of 200 Å˜300 Å. A part of the upper cap layer is removed to form a patterned upper cap layer by using the patterned mask layer as an etching mask. A part of the dielectric layer is removed to form a dielectric opening in the dielectric layer by using the patterned upper cap layer as an etching mask.

The following description is made with reference to the accompanying drawings.

### BRIEF DESCRIPTION OF THE DRAWINGS

FIGS. 1A-1F illustrate a method for forming a semiconductor structure according to one embodiment;

FIGS. 2A-2E illustrate a method for forming a semiconductor structure according to one embodiment; and

FIGS. 3A-3E illustrate a method for forming a semiconductor structure in comparative example.

### DETAILED DESCRIPTION

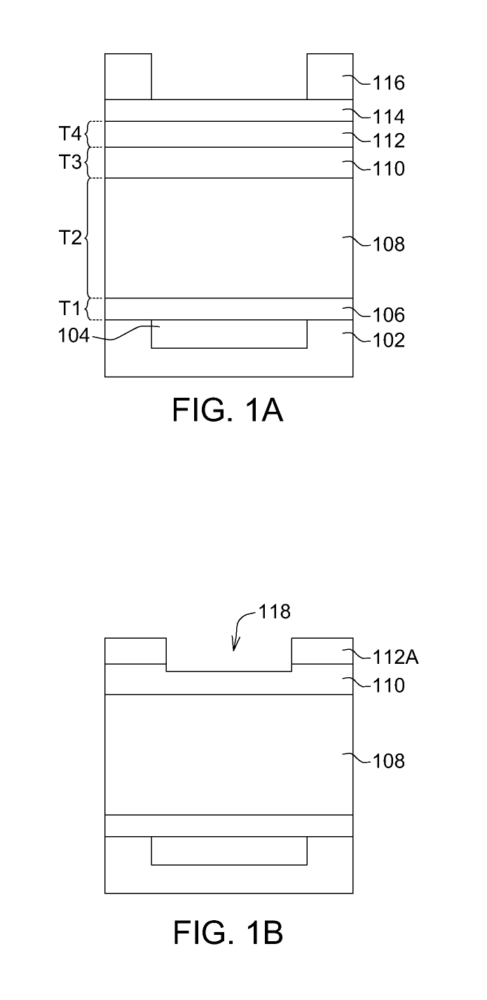

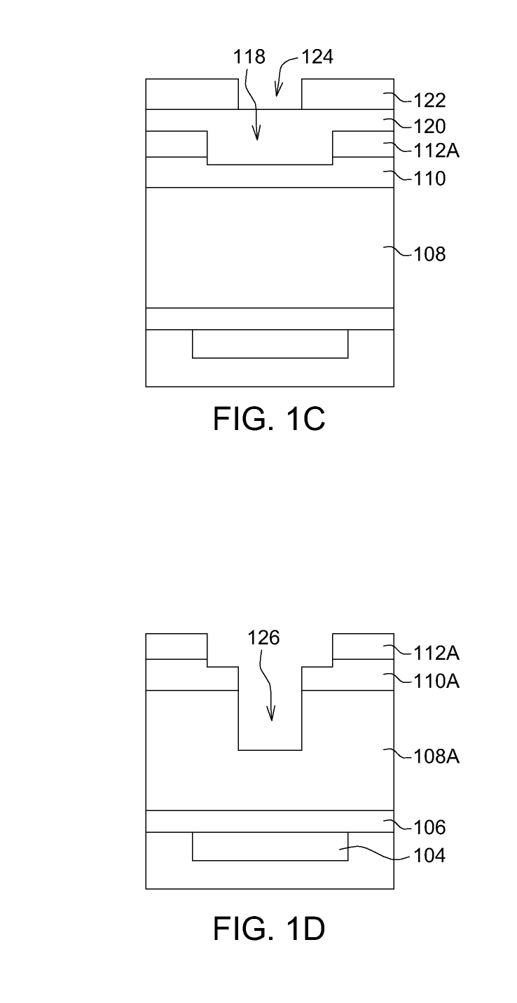

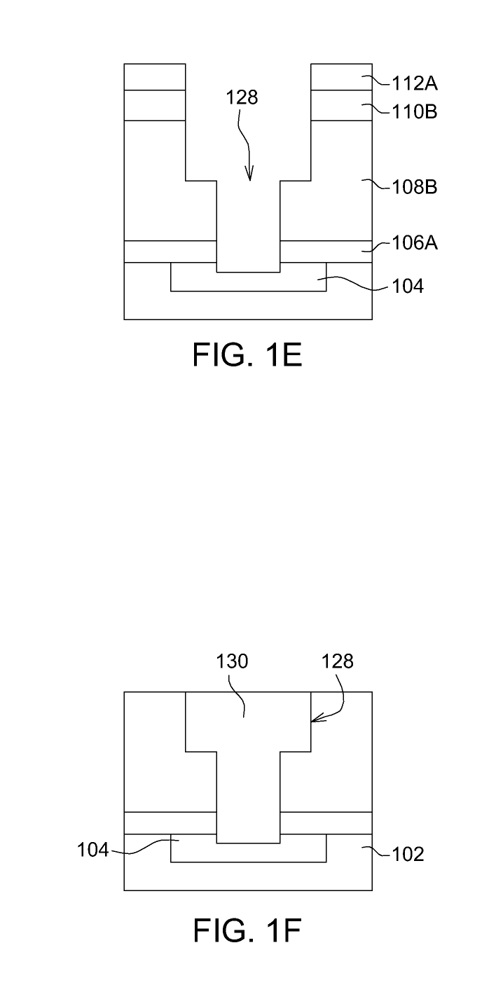

FIGS. 1A-1F illustrate a method for forming a semiconductor structure according to one embodiment.

Referring to FIG. 1A, a substrate 102 is provided. The substrate 102 has a conductive layer 104 therein. For example, the conductive layer 104 comprises a metal such as Cu, or other suitable materials. A lower cap layer 106 is formed on the substrate 102. The lower cap layer 106 has a lower cap thickness T1. The lower cap thickness T1 may have a range of 200 Å˜1500 Å, or other suitable sizes. The lower cap layer 106 may comprise silicon nitride or SiCHN, or other suitable materials. The lower cap layer 106 is not limited to a single-layer film as shown in FIG. 1A, and may be a multi-layer film.

A dielectric layer 108 is formed on the lower cap layer 106. The dielectric layer 108 comprises a low-K material such as hydwgem sisesquioxdne (HSQ), fluorosilicate glass (FSG), polyarylene ether (FLARE), SILK, polyparaxylylene (parylene), or other suitable materials. The dielectric layer 108 has a dielectric thickness T2. The dielectric thickness T2 has a range of 1000 Å˜5000 Å or 2000 Å˜5000 Å. The dielectric layer 108 may be formed by a depositing method such as PVD method, CVD method, a spin coating method, or other suitable methods.

An upper cap layer 110 is formed on the dielectric layer 108. The upper cap layer 110 is physically contacted with the dielectric layer 108. The upper cap layer 110 has an upper cap thickness T3. The upper cap thickness T3 has a range of 300 Å˜2000 Å. In embodiments, the upper cap layer 110 is a single-layer film. The upper cap layer 110 comprises a silicon oxide material. The upper cap layer 110 may be formed by a depositing method such as PVD method, CVD method or other suitable methods. For example, the upper cap layer 110 may comprise an oxide formed by a PECVD method (PEOX) or using tetra-ethyl-ortho-silicate (TEOS) as a precursor, or other suitable materials.

In embodiments, an etching step having the same parameter etches the upper cap layer 110 with an etching rate much slower than an etching rate to the dielectric layer 108, resulted from a structure of the upper cap layer 110 denser than a structure of the dielectric layer 108. A method for adjusting the structure characteristics of the films is to deposit the upper cap layer 110 with a depositing rate slower than a depositing rate for the dielectric layer 108. In some embodiments, the upper cap layer 110 is formed with a very low depositing rate such as smaller than 20 Å/sec (measured with a control wafer). In other embodiments, the structure characteristics of the films may be adjusted by other suitable methods.

A mask layer 112 is formed on and physically contacted with the upper cap layer 110. The mask layer 112 has a mask thickness T4 having a range of 200 Å˜300 Å. In embodiments, the mask layer 112 is a single-layer film. For example, the mask layer 112 comprises metal nitride such as TiN, or other suitable materials. In other embodiments, the mask layer 112 may be a multi-layer thin film such as a composite film of a Ti layer and a TiN layer.

An anti-reflective coating (ARC) 114 is formed on and physically contacted with the mask layer 112 optionally. The anti-reflective coating 114 is used for reducing reflecting issue during a photolithography exposure process. The anti-reflective coating 114 may comprise a top anti-reflective coating (TARC) and/or a bottom anti-reflective coating (BARC) that usually formed by an organic material. A patterned photo resist 116 is formed on the anti-reflective coating 114.

A pattern of the patterned photo resist 116 is transferred down into the mask layer 112 to form a patterned mask layer 112A shown in FIG. 1B by an etching step using the patterned photo resist 116 as an etching mask. Although this etching step is for removing the mask layer 112 mainly, it still etches the upper cap layer 110 under the mask layer 112 slightly in some embodiments. Next, the patterned photo resist 116 and the anti-reflective coating 114 are removed. Referring to FIG. 1B, the patterned mask layer 112A has a mask opening 118.

Referring to FIG. 1C, an anti-reflective coating 120 is formed on the upper cap layer 110 and the patterned mask layer 112A. A patterned photo resist 122 is formed on the anti-reflective coating 120. The patterned photo resist 122 has a photo resist opening 124. A location of the photo resist opening 124 is corresponded to a location of the mask opening 118.

A pattern of the patterned photo resist 122 is transferred down into the upper cap layer 110 to form an upper cap layer 110A shown in FIG. 1D and into the dielectric layer 108 to form an dielectric layer 108A having a dielectric aperture 126 therein shown in FIG. 1D by an etching step using the patterned photo resist 122 as an etching mask. Next, the patterned photo resist 122 and the anti-reflective coating 120 are removed.

Referring to FIG. 1D, a pattern of the patterned mask layer 112A is transferred down into an upper portion of the dielectric layer 108A and the dielectric aperture 126 is transferred down into a lower portion of the dielectric layer 108A and the lower cap layer 106 to form an dielectric opening 128 in a dielectric layer 108B and a patterned lower cap layer 106A which is a dual damascene opening as shown in FIG. 1E, by an etching step using the patterned mask layer 112A as an etching mask. Although this etching step is for removing the dielectric layer 108A and the lower cap layer 106 mainly, it still etches the conductive layer 104 under the lower cap layer 106 slightly in some embodiments. Moreover, since a transferring rate of the pattern of the patterned mask layer 112A is slower than a transferring rate of the dielectric aperture 126 due to a slow etching rate of the upper cap layer 110A in the step of transferring the pattern of the patterned mask layer 112A, an etched depth of a trench of the dielectric opening 128 would be shallower than an etched depth of a via of the dielectric opening 128.

Referring to FIG. 1F, a conductive material 130 is filled into the dielectric opening 128 as the dual damascene opening to form a conductive dual damascene structure coupled to the conductive layer 104 in the substrate 102. For example, the conductive material comprises a metal such as Cu, or other suitable materials. In embodiments, for example, the patterned upper cap layer 110B (FIG. 1E), the patterned mask layer 112A and an unnecessary part of the conductive material 130 may be removed by a CMP method simultaneously.

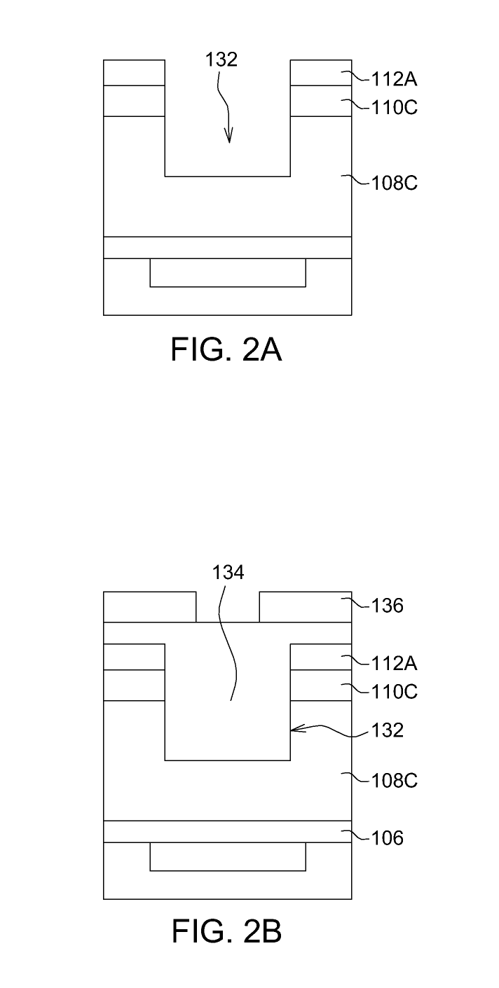

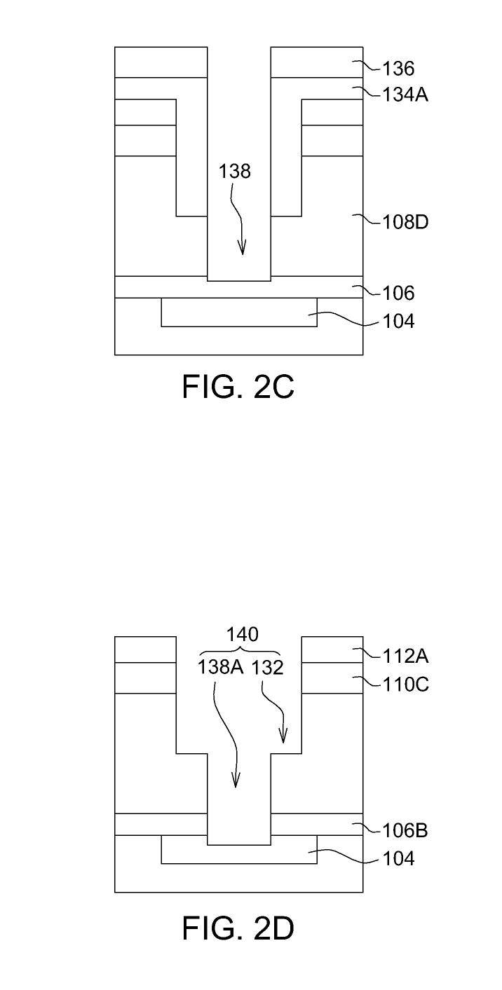

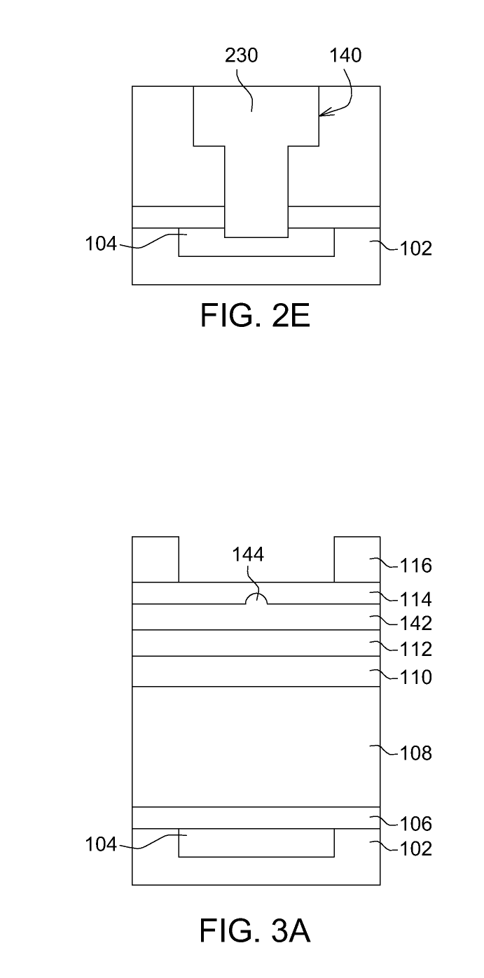

FIGS. 2A-2E illustrate the method for forming the semiconductor structure according to another embodiment. For example, the steps shown in FIGS. 1A-1B may be followed by steps shown in FIGS. 2A-2E.

Referring to FIG. 2A, the pattern of the patterned mask layer 112A is transferred down into the upper cap layer 110 (FIG. 1B) to form a patterned upper cap layer 110C by an etching step using the patterned mask layer 112A as an etching mask. In addition, a pattern of the patterned upper cap layer 110C is transferred down into the dielectric layer 108 to form a dielectric layer 108C having a dielectric opening 132 therein by an etching step using the patterned upper cap layer 110C as an etching mask. The patterned upper cap layer 110C and the dielectric layer 108C may be formed simultaneously by a single etching step.

Referring to FIG. 2B, an anti-reflective coating 134 is formed in the dielectric opening 132 and on the patterned mask layer 112A, the patterned upper cap layer 110C. A patterned photo resist 136 is formed on the anti-reflective coating 134.

A pattern of the patterned photo resist 136 is transferred down into the dielectric layer 108C by an etching step using the patterned photo resist 136 as an etching mask to form a dielectric layer 108D having a dielectric aperture 138 as shown in FIG. 2C. Although this etching step is for removing the dielectric layer 108C mainly, it still etches the lower cap layer 106 under the dielectric layer 108C slightly in some embodiments.

After the anti-reflective coating 134A and the patterned photo resist 136 are removed, the lower cap layer 106 exposed by the dielectric aperture 138 may be removed to form a lower cap layer 106B as shown in FIG. 2D by an etching step. The exposed dielectric opening 132 and dielectric aperture 138A form a dual damascene opening 140. The dielectric opening 132 is the trench of the dual damascene opening 140. The dielectric aperture 138 is the via of the dual damascene opening 140. Although this etching step is for removing the lower cap layer 106 (FIG. 2C) mainly, it still etches the conductive layer 104 under the lower cap layer 106 slightly in some embodiments.

Referring to FIG. 2E, the conductive material 230 is filled into the dual damascene opening 140 to form a conductive dual damascene structure coupled to the conductive layer 104 in the substrate 102.

In one embodiment, the patterned upper cap layer 110C, the patterned mask layer 112A (FIG. 2D) and an unnecessary portion of the conductive material 230 may be removed simultaneously by a CMP method, for example.

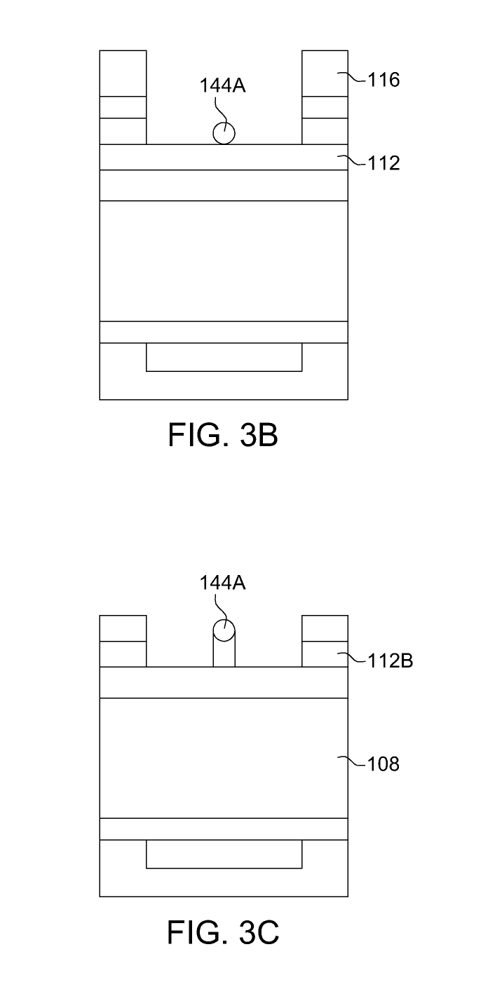

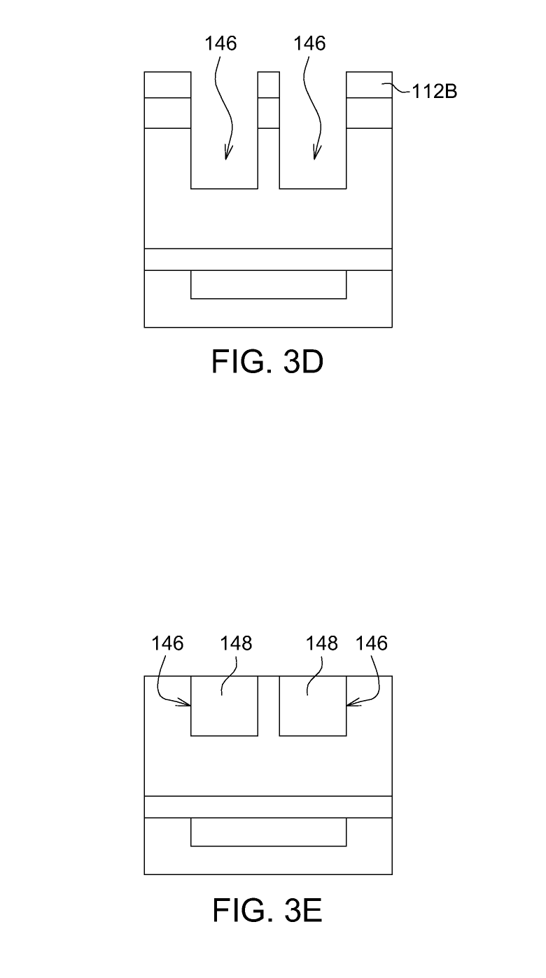

FIGS. 3A-3E illustrate a method for forming a semiconductor structure in one comparative example. The semiconductor structure in FIG. 3A is different form the semiconductor structure in FIG. 1A in that a silicon nitride containing layer 142 is formed on and physically contacted with the mask layer 112. The anti-reflective coating 114 is formed on the silicon nitride containing layer 142. Generally, a particle defect 144 is easily formed on a surface of the silicon nitride containing layer 142 during forming the silicon nitride containing layer 142.

Referring to FIG. 3B, the pattern of the patterned photo resist 116 is transferred down into the silicon nitride containing layer 142 by an etching step using the patterned photo resist 116 as an etching mask. Generally, the etching step for removing the silicon nitride containing layer 142 comprise silicon oxynitride for example has low etching selectivity to the mask layer 112 comprises TiN for example, therefore this etching step is controlled to just remove the film portion of the silicon nitride containing layer 142 substantially, and it results in a particle defect 144A transferred and remained on the mask layer 112 easily.

Referring to FIG. 3C, it is hard for the following removing step for the mask layer 112, comprising TiN for example, to remove the (silicon nitride containing) particle defect 144A. Therefore, the particle defect 144A becomes the etching mask for the mask layer 112 (FIG. 3B), and an etched mask layer 112B (FIG. 3C) can not have an expected pattern. In addition, a dielectric opening 146 (FIG. 3D) of un-expected pattern is formed by the following etching step for the dielectric layer 108. As a result, a conductive structure 148 (FIG. 3E) formed in the dielectric opening 146 generate a problem usually referred as to line broken. It reduces product yield.

Embodiments illustrated in FIGS. 1A-2E use the two-layer sacrificial film formed by the upper cap layer 110 and the mask layer 112. In contrast, comparative example illustrate in FIGS. 3A-3E uses the three-layer sacrificial film formed by the upper cap layer 110, the mask layer 112 and the silicon nitride containing layer 142. In other words, the layer number of the sacrificial film in embodiments is less than the layer number of the sacrificial film in comparative example, thus the semiconductor structure in embodiments can have a simpler manufacturing process and lower cost than the semiconductor structure in comparative example. Moreover, embodiments use the sacrificial film having no silicon nitride material, thus the line broken problem would not happen and product yield can be improved.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for forming a semiconductor structure, comprising:
forming an upper cap layer on and physically contacted with a dielectric layer, the dielectric layer having a dielectric thickness having a range of 1000 Å˜5000 Å;
forming a patterned mask layer on and physically contacted with the upper cap layer;
removing a part of the upper cap layer to form a patterned upper cap layer by using the patterned mask layer as an etching mask; and
removing a part of the dielectric layer to form a dielectric opening in the dielectric layer by using the patterned upper cap layer as an etching mask.

2. The method for forming the semiconductor structure according to claim 1, wherein the dielectric thickness has a range of 2000 Å˜5000 Å.

3. The method for forming the semiconductor structure according to claim 1, wherein the dielectric layer comprises a low-K material.

4. The method for forming the semiconductor structure according to claim 1, wherein the upper cap layer has an upper cap thickness having a range of 300 Å˜2000 Å.

5. The method for forming the semiconductor structure according to claim 1, wherein the upper cap layer is a single-layer film, the upper cap layer comprises a silicon oxide material.

6. The method for forming the semiconductor structure according to claim 1, wherein the method for forming the patterned mask layer comprises:
forming a mask layer on and physically contacted with the upper cap layer; and
removing a part of the mask layer to form the patterned mask layer.

7. The method for forming the semiconductor structure according to claim 6, wherein the mask layer comprises TiN.

8. The method for forming the semiconductor structure according to claim 6, wherein the mask layer has a mask thickness having a range of 200 Å˜300 Å.

9. The method for forming the semiconductor structure according to claim 6, further comprising forming a patterned photo resist on the mask layer, wherein the part of the mask layer is removed by using the patterned photo resist as an etching mask.

10. The method for forming the semiconductor structure according to claim 6, further comprising:
forming an anti-reflective coating on and physically contacted with the mask layer; and
forming a patterned photo resist on the anti-reflective coating, wherein the part of the mask layer is removed by using the patterned photo resist as an etching mask.

11. The method for forming the semiconductor structure according to claim 1, wherein the upper cap layer is formed by a depositing method, the dielectric layer is formed by a depositing method, a depositing rate of the upper cap layer is smaller than a depositing rate of the dielectric layer.

12. The method for forming the semiconductor structure according to claim 1, further comprising:
forming a lower cap layer on a substrate; and
forming the dielectric layer on the lower cap layer.

13. The method for forming the semiconductor structure according to claim 12, wherein the lower cap layer has a lower cap thickness having a range of 200 Å˜1500 Å.

14. The method for forming the semiconductor structure according to claim 1, further comprising forming a conductive material in the dielectric opening.

15. The method for forming the semiconductor structure according to claim 14, further comprising forming the dielectric layer on a substrate having a conductive layer therein, wherein the conductive material is coupled to the conductive layer.

16. The method for forming the semiconductor structure according to claim 1, wherein the dielectric opening is a dual damascene opening.

17. The method for forming the semiconductor structure according to claim 1, further comprising:
forming a patterned photo resist on the patterned mask layer, wherein the patterned photo resist has a photo resist opening, the patterned mask layer has a mask opening, a location of the photo resist opening is corresponded to a location of the mask opening; and
removing a part of the dielectric layer to form a dielectric aperture in the dielectric layer by using the patterned photo resist as an etching mask.

18. The method for forming the semiconductor structure according to claim 17, wherein the step for forming the dielectric opening is after the step for forming the dielectric aperture, the dielectric opening is a dual damascene opening.

19. The method for forming the semiconductor structure according to claim 17, wherein the step for forming the dielectric opening is before the step for forming the dielectric aperture, the dielectric opening and the dielectric aperture form a dual damascene opening, the dielectric opening is a trench of the dual damascene opening, the dielectric aperture is a via of the dual damascene opening.

20. A method for patterning a dielectric layer, comprising:
forming an upper cap layer on and physically contacted with a dielectric layer, the dielectric layer having a dielectric thickness having a range of 1000 Å˜5000 Å, the upper cap layer having an upper cap thickness having a range of 300 Å˜2000 Å;
forming a patterned mask layer on and physically contacted with the upper cap layer, wherein the patterned mask layer has a mask thickness having a range of 200 Å˜300 Å;
removing a part of the upper cap layer to form a patterned upper cap layer by using the patterned mask layer as an etching mask; and
removing a part of the dielectric layer to form a dielectric opening in the dielectric layer by using the patterned upper cap layer as an etching mask.
